(19) United States
(12) Patent Application Publication
(10) Pub. No.: US 2005/0198222 A1
(43) Pub. Date: Sep. 8, 2005

(54) Network device

(75) Inventors: Nobuaki Kohinata, Yokohama (JP); Mika Mizutani, Tokyo (JP); Toshihiro Yamagishi, Yokohama (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hitachi, Ltd., Tokyo (JP)

(21) Appl. No.: 10/857,094

(22) Filed: May 27, 2004

(30) Foreign Application Priority Data
Dec. 19, 2003 (JP) 2003-422738

(51) Int. Cl. G06F 15/177; G06F 13/12; G03F 3/08

(52) U.S. Cl. 709/220; 710/62

(57) ABSTRACT

There are disclosed a digital device in compliance with UPnP and its telecommunication method for restructuring a device description in accordance with a change of arrangements of own digital devices, such as a change of connection of extended peripheral devices, for example, and transmitting and reflecting a restructured device description to other digital devices. It is determined whether or not a change for the peripheral device of the own digital device is made by referring to a device information table stored in a memory for storing information for the peripheral device included in the own digital device. If it is determined that there is a change for the peripheral devices as a result, the device description is obtained and further a device name of the peripheral device associated with the change is obtained from the device information table. Then, the device description is updated by executing a procedure for information for the device description based on the obtained device name. Information for indicating a location for storing the updated device description, such as a new advertise message describing URL, for example, is transmitted from the own digital device to a network.

### CLAIM OF PRIORITY

The present application claims priority from Japanese patent application serial No. 2003-422738, filed on Dec. 19, 2003, the content of which is hereby incorporated by reference into this application.

### BACKGROUND OF THE INVENTION

The present invention relates to a digital device utilized by connecting to a network. More particularly, this invention relates to an information processing system in compliance with a plug and play system, which provides a function of a device for another device so as to enable the other device to utilize it.

Recently, network information home electric appliances having a plug and play function capable of sharing the function with each other by exchanging predetermined information automatically between devices connected to a network are used. Technology, so-called Universal Plug and Play (hereinafter, refer to UPnP), has been known conventionally for realizing such a plug and play function.

On the other hand, if the foregoing network device is an AV device, IEEE1394 has been commonly used as a peripheral device connection means of the network device for setting in a customer station network. Thus, an information processing device has been known and disclosed in Japanese Unexamined Patent Publication No. 2003-8610, for example, for proving a bridge so as to control the network device in compliance with the IEEE1394 standard from the network device in compliance with the UPnP standard, or to control the network device in compliance with the UPnP standard from the network device in compliance with the IEEE1394 standard conversely. Further, technology for universal plug and play of realizing the plug and play means has been known as “Universal Plug and Play Device Architecture Version 1.0 (www.upnp.org),” for example.

A network device having a UPnP specification as the foregoing conventional technology does not include a function of dynamically restructuring a device description of the own device, thus information for its added device is not added to the device description even if an extended peripheral device it connected to a network device Accordingly, a remote user cannot acknowledge a connection state of the foregoing extended peripheral device from the network device used by the user, thus the remote user cannot use it as a result.

Further, in the case where an embedded device of a network device cannot be used because of malfunction, the remote user needs to use the foregoing embedded device without acknowledging this condition. Accordingly, in an actual attempt, an inconvenient result is brought about.

Further, the information processing device disclosed in the abovementioned patent application functions as a proxy, converts a command in compliance with the UPnP standard to an AV/C command in compliance with the IEEE 1394 standard, and provides a function of converting the AV/C command to the command in compliance with the UPnP standard conversely. Accordingly, the foregoing information processing device does not reconstruct the device description owned by the device itself.

### SUMMARY OF THE INVENTION

As indicated in the foregoing, there are problems, in which a conventional network device cannot reconstruct dynamically the device description owned by the network device itself corresponding to a change of device arrangements of the network devices and a new device description cannot be acknowledged to another network device by the network device itself. As a result, another problem arises, in which the conventional network device causes incomplete function sharing between mutual network devices.

The object of the present invention is to reconstruct the device description corresponding to a change of a digital device connected to a network. Further, another object of the present invention is to reflect a change of device arrangements of the digital devices themselves by notifying the reconstructed device description to another network device.

A digital device connected to a network includes a device description for describing a digital device arrangement as predetermined information in order to utilize a function provided by the digital device from another digital device, corresponding to Plug and Play (PnP) capable of providing the function, to the another digital device by communicating the predetermined information via the network by the digital device, and description restructuring means for updating the device description by detecting a change of an own device arrangement. Further, the network device further includes description notification means for notifying the device description updated by the description restructuring means to another network device

In the embodiments, the foregoing digital device is the network device as a device in compliance with the UPnP standard via the network. The foregoing digital device determines Whether or not an extended peripheral device can be informed publicly and provided to the other network device and whether or not the extended peripheral network device capable of being provided for the other network device is connected. Preferably, the device description is restructured by referring to a device information table for determining whether or not the embedded device included in the network device operates correctly.

According to the present invention, specified information, such as the device description, describing information for the peripheral device arrangement of the first device capable of connecting the peripheral device is transmitted to the second device via the network. Further, in a system capable of utilizing a peripheral device function included in the first device from the second device, information for the peripheral device included in the first device is stored in a memory as the device information table, for example. Then, it is determined whether or not this information indicates a change of the peripheral device of the first device by referring to this device information table. As a result of this determination, if it is found that a change associated with the peripheral device is caused, the foregoing device description is obtained, and further a device name of the peripheral device associated with its change is obtained from the device information table, and the device description is updated by processing information associated with the foregoing device description based on the obtained device name. An updated description is transmitted to the network from the first device with information for storing the updated device description, such as a new advertise message describing URL, for example.

The change associated with the peripheral device of the first device includes the extension of functions by adding the new peripheral device, the deletion of the peripheral device, the hiding of the peripheral device, etc. In the embodiments, the device description is updated by detecting such a change by referring to the device information table so as to reflect its change in the foregoing device description.

According to the present invention, even if the change of arrangements is caused to the own digital device, the device description can be updated by detecting its change. Further, the extended peripheral device can be utilized via the other digital device by giving the updated device description to the other digital device.

These and other objects, features and advantages of the present invention will become more apparent in light of the detailed description of a preferred embodiment thereof, as illustrated in the accompanying drawing.

### BRIEF DESCRIPTION OF THE DRAWINGS

FIG. 1 is a block diagram of a customer station network to which the present invention is applied;

FIG. 2 is an example of the structure of a device description (partial selection) of a network unit (device);

FIG. 3 is another example of the structure of a service description (partial selection) of the network device.

FIG. 4 is a block diagram of the network device of the first embodiment of the present invention;

FIG. 5 is an example of the device information table included in the network device of the first embodiment of the present invention;

FIG. 6A is a flowchart of executing the procedure of a description restructuring and notification program of the network device of the first embodiment of the present invention;

FIG. 6B is a flowchart of executing the procedure of the description restructuring and notification program of the network device of the first embodiment of the present invention;

FIG. 6C is a flowchart of executing the procedure of the description restructuring and notification program of the network device of the first embodiment of the present invention;

FIG. 6D is a flowchart of executing the procedure of the description restructuring and notification program of the network device of the first embodiment of the present invention;

FIG. 7 is an example of the device description included in the network unit (device).

FIG. 8 is an example of the device description restructured by the description restructuring and notification program.

FIG. 9 is a block diagram of the network structure for explaining the customer station network location of the network device of the first embodiment of the present invention.

FIG. 10 is a block diagram of the network devices according to the second embodiment of the present invention.

FIG. 11 is an example of a device information table 90 included in the network device of FIG. 10.

FIG. 12A is a flowchart of executing the procedure of the description restructuring and notification program of the network device of the second embodiment of the present invention.

FIG. 12B is a flowchart of executing the procedure of the description restructuring and notification program of the network device of the second embodiment of the present invention.

FIG. 12C is a flowchart of executing the procedure of the description restructuring and notification program of the network device of the second embodiment of the present invention.

FIG. 13 is an example of the restructured device description by the procedures of FIGS. 12A to 12C.

FIG. 14 is a block diagram of the customer station network structure for explaining the location of the network device in the customer station network of the second embodiment of the present invention.

### DETAILED DESCRIPTION OF THE PREFERRED EMBODIMENTS

In the following part, embodiments of a network device of the present invention are explained in detail with reference to drawings. The following embodiments of the present invention are capable of rebuilding a device description automatically without having the special hardware architecture by creating and managing, with use of software, a table for storing information for an embedded device and an extended. peripheral device connected to a network device.

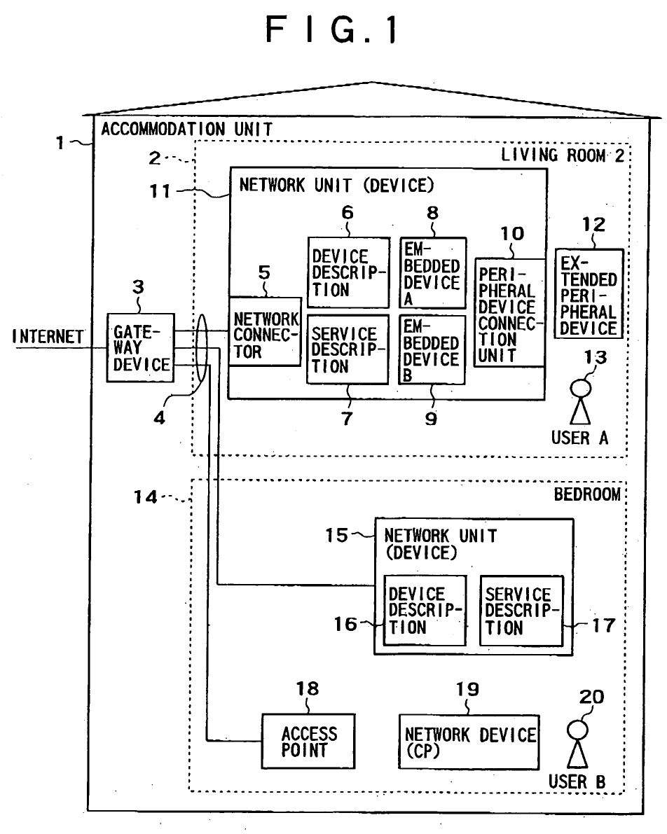

FIG. 1 is a block diagram of a customer station network of the present invention. First, an example of the customer station network diagram and a network information appliance in accordance with the UPnP standard for connecting a customer station network are explained. Here, according to the UPnP standard, the network information appliance is divided into two categories, devices and control points. The network information appliance capable of providing a self-embedded device to another device is defined as the device. The network information appliance for controlling and utilizing the device is defined as the control point. Here, a network information appliance for both the device and control point is also provided. In the following explanation, a device for a network information appliance is defined as a network unit (device), and the control point is defined as a network device (CP), which are based on the UPnP standard. In FIG. 1, a numeric reference 1 is a residence, a numeric reference 2 is a living room, a numeric reference 3 is a gateway device, a numeric reference 4 is a wire cable, a numeric reference 5 is a network unit (device), numeric references 6 and 16 are device descriptions, numeric references 7 and 17 are service descriptions, numeric references 8 and 9 are embedded devices A and B, a numeric reference 10 is a peripheral device connection unit, numeric references 11 and 15 are network devices (device), a numeric reference 12 is an extended peripheral device, numeric references 13 and 20 are users A and B, a numeric reference 14 Is a bedroom, a numeric reference 18 is an access point, and a numeric reference 19 is a network device (CP).

Here, as indicated in FIG. 1 as an example for explanation, the living room 2 and the bedroom 14 are provided as habitable rooms in the residence 1. The network unit (device) 11 and the extended peripheral device 12 are provided in the living room 2. The network unit (device) 15 and the access point 18 are provided in the bedroom 14. Further, the customer station network includes the network unit (device) 11 that is connected to a public switched network including Internet via the gateway device 3 and provided in the living room 2, a wire cable network unit that is directly connected by the gateway device 3 and the wire cable 4 in the same way as the network unit (device) 15 and the access point 18 provided in the bedroom 14, and a wireless network unit that is connected to the access point 18 in the same way as the network device (CP) 19 of the bedroom 14.

In the foregoing description, with respect to the network unit (device) 11, the network unit (device) 11 includes the network connector 5 for connecting to the customer station network, the peripheral device connection unit 10 that is connected to the extended peripheral device 12 so as to enable an extended function by the user A 13 and the user B 20, the embedded device A 8 and the embedded device B 9 (only two users are indicated as an example, but more than two users can be provided) so as to realize various physical and logical functions in order to provide for the user A 13 and the user B 20, the device description 6 of describing the whole structure of devices including the embedded device A 8 and the embedded device B9, and the service description 7 of describing more detail functions capable of performing actually the network unit (device) 11. Further, as indicated in FIG. 1, the network unit (device) 15 includes only a device description 16 and a service description 17. In the network unit (device) 11 and the network unit (device) 15, only one of the device descriptions 6 and 16 is necessarily provided. However, plural service descriptions 7 and 17 shall be provided since they depend on the structure of the embedded device and the number of functions.

As actual examples of network devices, such as the foraging network unit (device) 11, the network unit (device) 15, and the network device (CP) 19, there are a remote control device, a television set, a video camera, a DVD player; a hard disc recorder for storing an image and music contents, etc. As network connection means, there are provided, for example, a wireless LAN represented typically by Ethernet (registered trademark), a wireless LAN represented and defined by IEEE (Institute of Electrical and Electronics Engineers) 802.11b and IEEE 802.11a, and IEEE 802.11g. Further, in the event that the foregoing network unit (device) 11 is the hard disc recorder, as the case of the embedded device A 8 and the embedded device B 9, there is a hard disc function device having a timer function, a broadcasting Information receiving tuner, and its contents. Further the extended peripheral device 12 includes, for example, a hard disc drive, a digital video camera, a portable telephone, etc. The peripheral device connection means includes, for example, IDE, PCI, USB, IEEE 1394, etc.

Here, according to the UPnP standard, the control point detects a desired device and obtains Information in relation to its device element arrangement and detail functions, and further a telecommunication protocol and an operation sequence are defined. That is to say, the network device (CP) 19 acknowledges device arrangements and functions of the network unit (device) 11 and the network unit (device) 15 by obtaining the device description 6, the service description 7, the device description 16, and the service description 17. Then, the network device (CP) 19 can control and utilize the network unit (device) 11 of the living room 2 via the customer station network even from the user B 20 of the bedroom 14.

Then, a description obtainment process for the network device (CP) 19 to obtain the service description 7 and the device description 6 of the network unit (device) 11 is explained. Here the description obtainment process is used for the network unit (device) 15 in the same way.

In the UPnP standard, the description obtainment process is divided into two types of methods. The first method is the case in which the network unit (device) 11 functions as a trigger.

According to the first method, the foregoing network unit (device) 11 transmits an advertise message having a destination URL for storing the device description 6 and indicating that the network unit (device) 11 itself is a device in conformity with the UPnP standard to the customer station network by multicasting. Then, the network device (CP) 19 receives the foregoing advertise message and obtains the device description 6 by accessing the destination URL that is indicated in its message.

Further, the second method is the case in which the network device (CP) 19 functions as a trigger. According to the second method, the network device (CP) 19 transmits a device search message by multicasting to the customer station network, the network unit (device) 11, which has received the foregoing device search message, returns a search response message including the destination URL for storing the device description 6, and the network device (CP) 19 receives the foregoing search response message and obtains the device description 6 by accessing URL that is indicated in its message.

On the other hand, the destination URL of the service description 7 is indicated in the foregoing device description 6 as indicated in the latter part of the specification. Thus, the network device (CP) 19 can obtain the service description 7 successively from the foregoing device description 6.

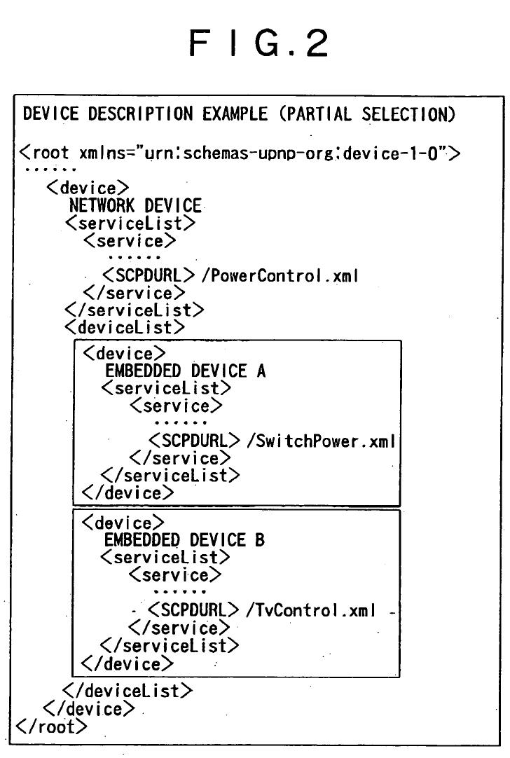

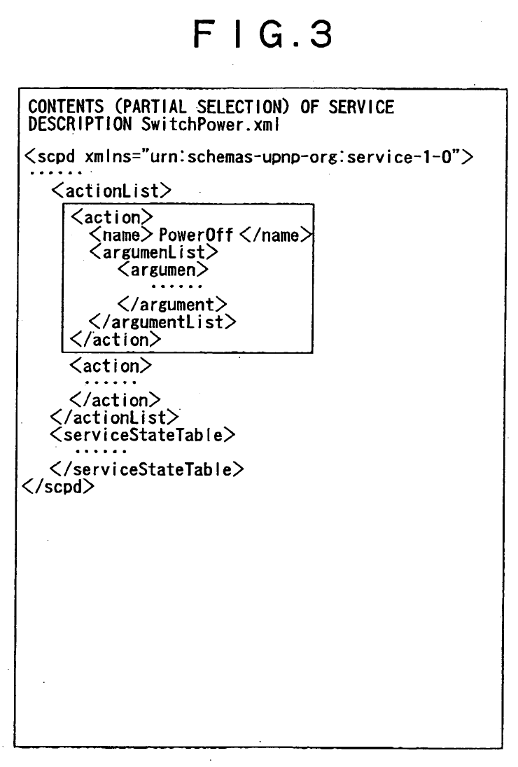

FIG. 2 is an explanatory view of the structure of the device description (extract) included in the network unit (device). FIG. 3 is an explanatory view of the structure of the service description (extract) included in the network unit (device). Then, these figures are explained.

As indicated in FIG. 2, the device description is a language description in which the network unit (device) is described by the XML language. To put it concretely, the embedded device A 8 and the embedded device B 9 of the network unit (device) 11 of FIG. 1, as indicated using an enclosing thin line in FIG. 2, are listed using a <device>tag in a portion having a start tag of <deviceList>. Further, a function provided by each embedded device is described using a <service>tag, and the destination URL is described using a <SCPDURL>tag of a service description describing these detail functions using the XML language.

Then, the description of FIG. 3 indicates only the service description (extract) corresponding to the embedded device A 8. An action or a command for replying to a request from the network unit (CP) is described by a <action>tag (as indicated by enclosing thin line in FIG. 3). Parameters and state variables for the command and the action are described using a <argument>. tag and a <serviceStateTable>tag respectively.

Since the network unit (device) 11 connected to the foregoing customer station network does not include a function for restructuring dynamically the device description 6, even if the extended peripheral device 12 is connected to the peripheral device connection unit 10 of the network unit (device) 11 or embedded devices fail to function, malfunction information is not added to the device description 6 and the remote user B 20 cannot acknowledge a connection state of the extended peripheral device 12. As a result, the network unit (device) 11 cannot be utilized and it causes inconvenience in the event that the specification is described in such a way that malfunction embedded device is used.

On the other hand, although the network device (CP) 19 connected to the customer station network obtains the device description 6 by a device search message issued by itself or the advertise message issued regularly from the network unit (device) 11 and the network unit (device) 15 at each timing, even if the device description 6 is updated by a restructuring operation, its operation and the description obtainment process are not linked with each other. Thus, it is impossible to obtain a new device description of network unit (device) 11 and the network unit (device) 15 and then acknowledge the latest element arrangement and usable functions.

The embodiments of the present invention are to restructure dynamically the device description in the foregoing network devices and to notify the fact of restructuring the device description to other network devices.

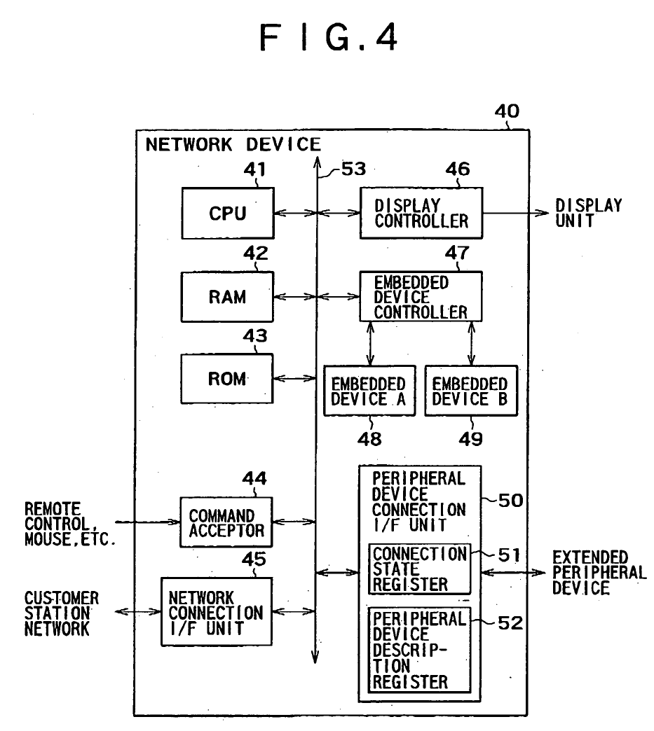

FIG. 4 is a block diagram of a network device of the first embodiment of the present invention. In FIG. 4, a numeric reference 40 is a network device, a numeric reference 41 is a CPU, a numeric reference 42 is a RAM, a numeric reference 43 is a ROM, a numeric reference 44 is a command acceptor, a numeric reference 45 is a network connection I/F unit, a numeric reference 46 is a display controller, a numeric reference 47 is an embedded device controller, a numeric reference 48 is an embedded device A, a numeric reference 49 is an embedded device B, a numeric reference 50 is a peripheral device connection I/F unit, a numeric reference 51 is a connection state register, and a numeric reference 52 is a peripheral device description register.

The network unit (device) 40 of FIG. 4 is a device in compliance with the UPnP standard. The network unit (device) 40 is a network device corresponding to each of the network units (devices) 11 and 15 of FIG. 1 This network unit (device) 40 includes the CPU 41, the RAM 42, the ROM 43, the command acceptor 44, the network connection I/F unit 45, the display controller 46, the embedded device controller 47, the embedded devices A 48 and B 49 (corresponding to embedded devices A 8 and B 9) connected to this embedded device controller 47, the peripheral device connection I/F unit 50, the peripheral device description register 52 and the peripheral device description register 51 included in this peripheral device connection I/F unit 50, and a description restructuring means that is explained in the latter portion of the specification.

In the foregoing description, the network connection I/F unit 45 is a customer station network connection means. In the case of connecting to the wireless network, a wire system telecommunication protocol such as Ethernet (registered mark), for example, is provided. In the case of connecting to a wireless network, a wireless system telecommunication protocol such as IEEE 802.11b, IEEE 802.11a, IEEE 802.11g protocol is provided. Further, the network connection I/F unit 45 is so structured as for the wire and wireless telecommunication protocol to be possibly provided in order to be connected to any of the wire network -and the wireless network.

The peripheral device connection I/F unit 50 includes the peripheral device description register 51 as an expanded capability means for connecting an extended peripheral device such as a hard disc drive, a small size semiconductor memory, a DVD drive, a digital camera, a digital video camera, the portable telephone by the user and controlling a connection state and device intrinsic information such as a vendor code and a serial number and a support function of an extended peripheral device, which indicates the physical connection state of the extended peripheral devices and has one-to-one correspondence with each extended peripheral device. The peripheral device connection I/F unit 50 further includes the peripheral device description register 52 for storing device intrinsic information that is obtained from the extended peripheral devices. The peripheral device connection I/F unit 50 is so structured as to possibly provide any one of interfaces adaptable for connecting the extended peripheral devices such as USB, IEEE 1394, PC card I/F, etc. or plural combination thereof.

The command acceptor 44, which is a command acceptor means for accepting various instructions from the user, connects an indication input device such as a mouse and a key board, and includes a light receiving unit for receiving an infrared ray by remote control.

The display controller 46 is a display means for the user. The display controller 46 can provide a device element arrangement and various internal states of the network unit (device) 40, a connection state of the extended peripheral device and a running state of the embedded device, and an instruction from the user which is received by the foregoing command acceptor 44 to the display unit using a data format adaptable for the display unit.

The embedded device controller 47 is a control means for arbitrating the operation of each embedded device, although the case of connecting only two of embedded devices A 48 and B 49 is indicated in FIG. 4. To put it concretely, in the event that the network unit (device) 40 is the hard disc recorder, as functions provided by the embedded device A 48 and embedded device B 49, there are a timer function, a broadcasting information receiving tuner function, and an image compression expansion function for transmitting contents, which are stored by compressing received contents or compressed by the user requests, by expanding from the display controller 46 to the display unit. The embedded device controller 47 controls and arbitrates the rights of using an internal bus 53 in the event that the received contents are stored and stored contents compete with each other.

The description restructuring means, the details of which will be described later, is structured in the ROM 43 and realized by CPU processing. The description restructuring means is a decision means for deciding whether or not extended peripheral devices can be opened publicly and provided to other network devices or whether or not an extended peripheral device which can be provided to other network devices is connected, when the extended peripheral devices are connected to the peripheral device connection I/F unit 50 of the network unit (device) 40. The description restructuring means functionally describes a list of the extended peripheral devices, stores a device information table which can be compiled by the user using a device of providing a user interface such as the remote control with reference to the device element arrangement that is output to the display unit, stores the service description and the device description provided by the network unit (device) 40 to the current network devices and the service description that is prepared In advance so as to respond to the available extended peripheral device described in the foregoing device information table, and restructures the foregoing device description and the service description by accepting indication from the peripheral device connection I/F unit 50 as a function expansion means, the embedded device controller 47 as an embedded device management means,.and the command acceptor 44 as a command input means from the user.

The ROM 43 stores a program of restructuring and notifying the description as a software program for providing a description notification means of providing a series of sequences for notifying that the device description is restructured and updated by a restructure means of the description. Further, ROM 43 stores OS (operating software) and a web server software.

The CPU 41 and RAM 42 execute the foregoing description restructuring means, a notification program, OS (Operating System)., and web server software.

Here, the network unit (device) 40 performs compiling operation by loading the device information table stored in the foregoing ROM 43 into the RAM 42 using an initialization program after the power supply is turned on and stores the device information table in ROM 43 at regular time intervals even during operation or at the time of terminating the operation by turning-off the power supply, etc.

Further, the network unit (device) 40 can store contents stored in the foregoing ROM 43 in a mass storage means such as the hard disc, in the case of having the mass storage means such as the hard disc. Then, the CPU 41, RAM 42, ROM 43, command acceptor 44, network connection I/F unit 45, display controller 46, the embedded device controller 47, and the peripheral device connection I/F unit 50 are connected with each other by the internal bus 53, and data and commands can be exchanged with each other as required.

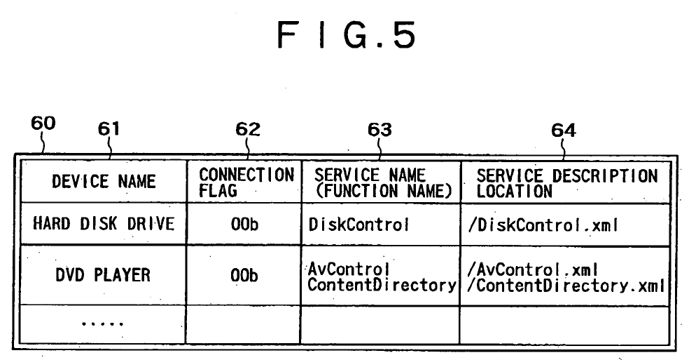

FIG. 5 is an example of the device information table included in the network device of the first embodiment of the present invention. Then this device information table is explained below.

As indicated in FIG. 5, a device information table 60 stores a device name 61 for indicating an extended peripheral device which can be provided by the network unit (device) 40 of FIG. 4 to another network device, a connection flag 62 which indicates at least a connection state of the extended peripheral device, reflection condition to the device description, etc., and can be edited by the user, a service name (function name) 63 included in the extended peripheral device that is described in the foregoing device name 61, and a service description. location 64 that indicates the service description and its location which corresponds to the foregoing service name (function name) 63 and indicates the service description and its location stored by the foregoing network unit (device) 40 in advance.

The foregoing connection flag 62 describes “01b” (“b” stands for binary) that indicates only a connection state right after the extended peripheral device in conformity with the device name 61 is connected to the peripheral device connection I/F unit 50 of the network unit (device) 40 of FIG. 4. Then, the connection flag 62 describes “11b” that indicates the connection state and the reflection condition (addition) to the device description at the stage of adding the foregoing extended peripheral device to the device description. Further, the connection flag 62 describes “10b” that indicates only a non-connection state right after the foregoing extended peripheral device is removed, and “00b” that indicates the [symbol] non-connection state and a reflection condition (deletion) to the device description at the stage of deleting the device description. Further, the user can edit only bit portions for indicating reflection condition to the description of the foregoing connection flag 62. The user can change the connection flag 62 from “11b” to “01b” and from “01b” to “11b.” Here, the initial condition of the connection flag 62 is “00b.”

Then, with reference to FIG. 4, the operation of the network unit (device) 40 when the user has added the extended peripheral device to the peripheral device connection I/F unit 50 is explained.

If the extended peripheral device is connected to the peripheral device connection I/F unit 50, the foregoing peripheral device connection I/F unit 50 issues a peripheral device connection notification that indicates the extended peripheral device is connected to CPU 41. Although an actual method for transmitting this peripheral device connection notification is not shown in FIG. 4, this method can be realized by utilizing an interrupting signal for making point-to-point connection between CPU 41 and the peripheral device connection I/F unit 50.

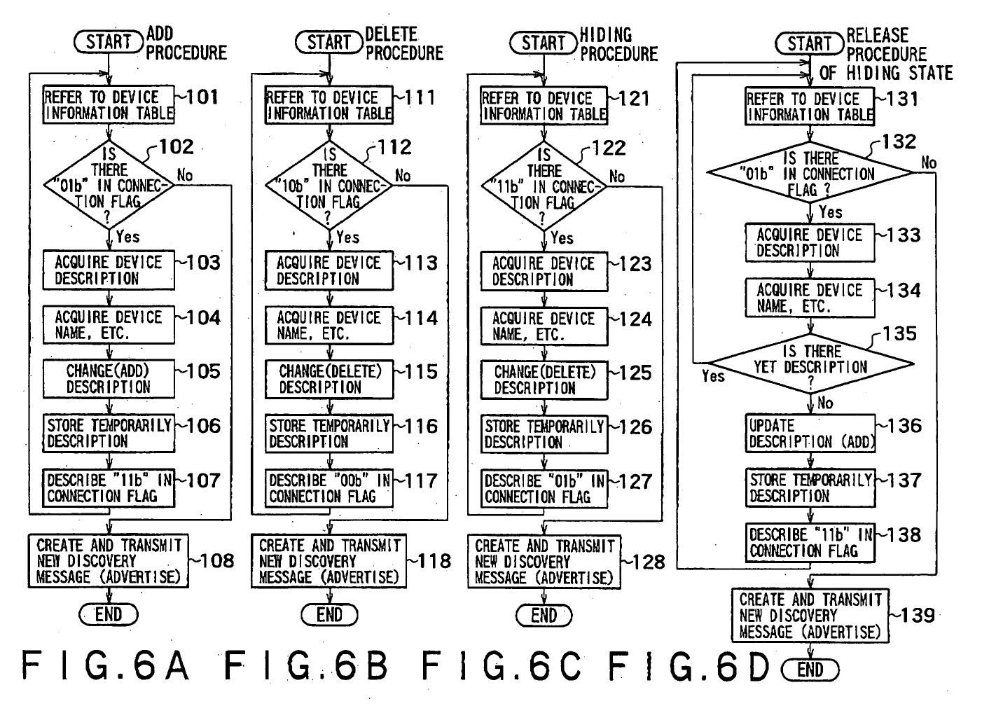

When the CPU 41 receives the foregoing peripheral device connection notification, the CPU 41 refers to the peripheral device description register 52 and the peripheral device description register 51 of the peripheral device connection I/F unit 50 in order to identify the connected extended peripheral device. Then, the CPU 41 obtains suitable. 20 information from the foregoing peripheral device description register 52. Further, the CPU 41 refers to the device information table, and determines that it is possible to provide the information to the network device (CP) if the connected expanded peripheral device is described in the device information table 60 of FIG. 5. Then, the CPU 41 describes “01b” in the connection flag 62 of the foregoing device information table 60, and activates a description restructuring and notification program in an additional procedure to be hereinafter described by the flowcharts of FIGS. 6A to 6D.

On the other hand, if the connected expanded peripheral device is not described in the device information table 60, the CPU 41 notifies the user that the expanded peripheral device which cannot be reflected in the device description is connected by outputting a sign thereof in the display via the display controller 46. In this case, the foregoing description restructuring and notification program is not activated.

Here, the operation when the expanded peripheral device is removed is explained.

If the expanded peripheral device is removed from the peripheral device connection I/F unit 50, the peripheral device connection I/F unit 50 issues a peripheral device removal notification to the CPU 41 to indicate that the expanded peripheral device is removed. Although an actual method for transmitting this peripheral device removal notification is not indicated in FIG. 4, this method can be realized by utilizing an interrupting signal for making point-to-point connection between the CPU 41 and the peripheral device connection I/F unit 50.

If the CPU 41 receives the foregoing peripheral device removal notification, the CPU 41 refers to the peripheral device description register 52 and the peripheral device description register 51 of the peripheral device connection I/F unit 50 in order to identify the removed extended peripheral device. Then, the CPU 41 obtains suitable information from the foregoing peripheral device description register 52. Further, CPU 41 refers to the device information table, and identifies that it is impossible to provide for the network device (CP) if the removed expanded peripheral device is described in the device information table 60 of FIG. 5. Then, the CPU 41 describes “10b” in the connection flag 62 of the foregoing device information table 60, and activates the description restructuring and notification program of a deletion procedure to be hereinafter described by the flowcharts of FIGS. 6A to 6D.

On the other hand, if the removed expanded peripheral device is not described in the device information table 60, the CPU 41 does not activate the foregoing description restructuring and notification program.

Here, the description restructuring and notification program is activated If the user changes the connection flag 62 of the device information table 60 of FIG. 5. In this way, the connection flag 62 may be changed by the user when the foregoing expanded peripheral device is removed from the device description so as to hide the connected expanded peripheral device in order not to provide to another network device, for example. In this case, to put it concretely, the condition of the foregoing connection flag 62 is updated from “11b” to “01b” by the user. If the connection flag 62 is changed in this way, the description restructuring and notification program indicated in the hide procedure of the flowchart of FIG. 6C is activated. Further, if the foregoing expanded peripheral device is added to the device description in order to release the hiding state of the connected expanded peripheral device after the foregoing hide procedure Is executed, the user updates the condition of the foregoing connection flag 62 from “01b” to “11b.” In this case, the description restructuring and notification program indicated for releasing the hiding state of the flowchart of FIG. 6D is activated.

The foregoing hiding state is needed in the case of prohibiting further usage by the remote user if the connected expanded peripheral device is the hard disc drive, for example, and its empty capacity is not enough. Further, such a condition is needed in the case of prohibiting accessing by the remote user if the connected expanded peripheral device is a DVD drive and contents cannot be sent to the network because of its nature.

FIGS. 6A to 6D are flowcharts of explaining the execution of the procedures of the description restructuring and notification programs of the network devices of the first embodiment of the present invention. Then, this flowchart is explained hereinafter. If the expanded peripheral device described in the device information table is connected, or removed, or a bit string for reflecting the connection flag of the device information table in the description is changed by the user explicitly, the procedures of the description restructuring and notification programs are executed.

First, the procedure of adding information of the connected extended peripheral device to the device description is explained with reference to the flowchart of FIG. 6A.

(1) If the extended peripheral device is connected, the connection flag 62 of the device information table 60 is referred to, the line of describing “01b” in the connection flag, namely, the line of indicating the condition of connecting its extended peripheral device, is searched, and it is made to determine whether or not the corresponding line exists as a result of searching (steps 101 and 102).

(2) If it is determined that there is the line of describing “01b” in the connection flag according to the determination of the step 102, the current device description is obtained from a memory, and further the device name, the service name, and the service description location are obtained from the device information table 60 (steps 103 and 104).

(3) The <device>tag Is added to the <deviceList>tag portion of the device description obtained at the step 103, information obtained at the step 104 is added, and the device description is stored temporarily in the memory (steps 105 and 106)

(4) Then, the flag “11b” indicating that the connected extended peripheral device is registered in the device description is described in the connection flag of the device information table. Then, returning to the procedures from the step 101, the procedure of a line for searching successively is transferred and executed (step 107).

(5) Then, according to the determination at the step 102, in the event that the line of describing “01b” in the connection flag does not exist in the device information table any more, multicasting transmission is made by creating a new advertise message describing URL for storing the latest device description (step.108).

Then, with reference to the flowchart of FIG. 6B, the procedure for deleting information of the extended peripheral device removed from the device description, in the case where the connected extended peripheral device is removed, is explained.

(1) If the extended peripheral device is removed, the connection flag 62 of the device information table 60 is referred to, the line of describing “10b” in the connection flag, namely, the line of indicating the condition of disconnecting its extended peripheral device, is searched, and it is determined whether or not the corresponding line exists as a result of searching (steps 111 and 112).

(2) If it is determined that there is the line of describing “10b” in the connection flag according to the determination of the step 112, the current device description is obtained from the memory, and further the device name is obtained from the device information table 60 (steps 113 and 114).

(3) The tag portions up to a </device>tag from the <device>tag describing the extended peripheral device obtained at the step 114 are deleted from the <deviceList>tag portion of the device description obtained at the step 113, then the device description is stored temporarily in the memory (steps 115 and 116).

(4) Then, the flag “00b” indicating that the disconnected extended peripheral device Is deleted from the device description is described in the connection flag of the device information table. Then, returning to the procedures from the step 111, the procedure of a line for searching successively is transferred and executed (step 117).

(5) Then, according to the determination at the step 112, the event that the line of describing “10b” in the connection flag does not exist in the device information table any more, multicasting transmission is made by creating a new advertise message describing URL for storing the latest device description (step 118).

Then, with reference to the flowchart of FIG. 6C, the procedure for deleting information of the extended peripheral device from the device description, in order to hide the connected extended peripheral device, is explained.

(1) If the procedure of hiding the extended peripheral device is started, the connection flag 62 of the device information table 60 is referred to the line of describing “11b” in the connection flag, namely, the line of indicating that the extended peripheral device can be provided for the outside, is searched, and it is determined whether or not the corresponding line exists as a result of searching (steps 121 and 122).

(2) If it is determined that there is the line of describing “11b” in the connection flag according to the determination of the step 122, the current device description is obtained from the memory, and further the device name is obtained from the device information table 60 (steps 123 and 124).

(3) The tag portions up to a </device>tag from the <device>tag describing the extended peripheral device obtained at the step 124 are deleted from the <deviceList>tag portion of the device description obtained at the step 123, then the device description is stored temporarily in the memory (steps 125 and 126).

(4) Then, the flag “01b” indicating that the hiding extended peripheral device is deleted from the device description is described in the connection flag of the device information table. Then, returning to the procedures from the step 111, the procedure of a line for searching successively is transferred and executed (step 127).

(5) Then, according to the determination at the step 122, in the event that the line of the hiding device describing “11b” in the connection flag does not exist in the device information table any more, multicasting transmission is made by creating a new advertise message describing URL for storing the latest device description (step.128).

Then, with reference to the flowchart of FIG. 6D, the procedure for adding information of the extended peripheral device to the device description, in order to release the hiding state of the connected and hidden extended peripheral device, is explained.

(1) If the procedure of releasing the hiding state is started, the connection flag 62 of the device information table 60 is referred to, the line of describing “01b” in the connection flag, namely, the line of indicating that the extended peripheral device cannot be provided to the outside, is searched, and it is determined whether or not the corresponding line exists as a result of searching (steps 131 and 132).

(2) If it is determined that there is the line of describing “01b” in the connection flag according to the determination of the step 132, the current device description is obtained from a memory, and further the device name, the service name, and the service description are obtained from the device information table 60 (steps 133 and 134).

(3) It is determined whether or not the device name obtained in the step 134 has already been described in the device description obtained at the step 133, and if the device name has already been described, the procedure of a line for searching successively is executed by transferring to the step 131 (step 135).

(4) If the device name obtained at the step 134 is not described in the device description by determining at the step 135, the <device>tag is added to the <deviceList>tag portion of the device description obtained at the step 133, information obtained at the step 134 is added, thus restructured device description is temporarily stored in the memory (steps 136 and 137).

Then, the flag “11b” is described in the connection flag of the device information table, returning to the procedures from the step 131, and the procedure of a line for searching successively is transferred and executed (step 138).

(6) Then, according to the determination at the step 132, if the line of releasing the hiding state of the device describing “01b” in the connection flag does not exist in the device information table any more, multicasting transmission is made by creating a new advertise message describing URL for storing the latest device description (step 139).

In the foregoing, the execution of the procedures of the description restructuring and notification programs are explained, and the network device (CP) can obtain the restructured device description by receiving the foregoing new advertise message and accessing the destination URL.

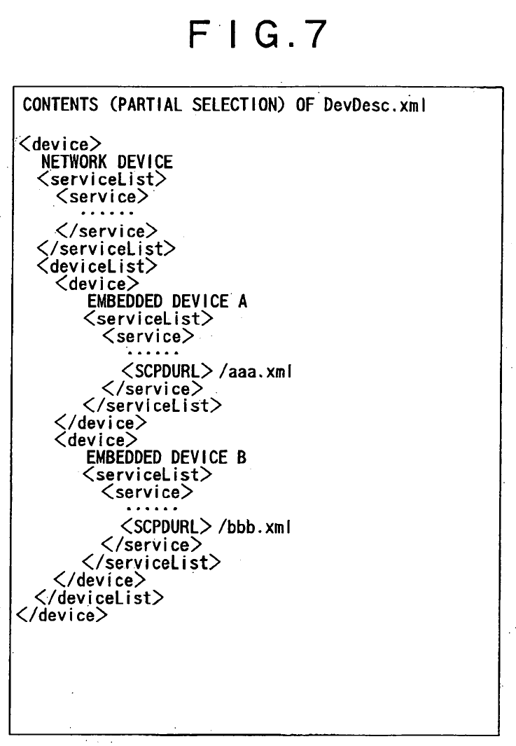

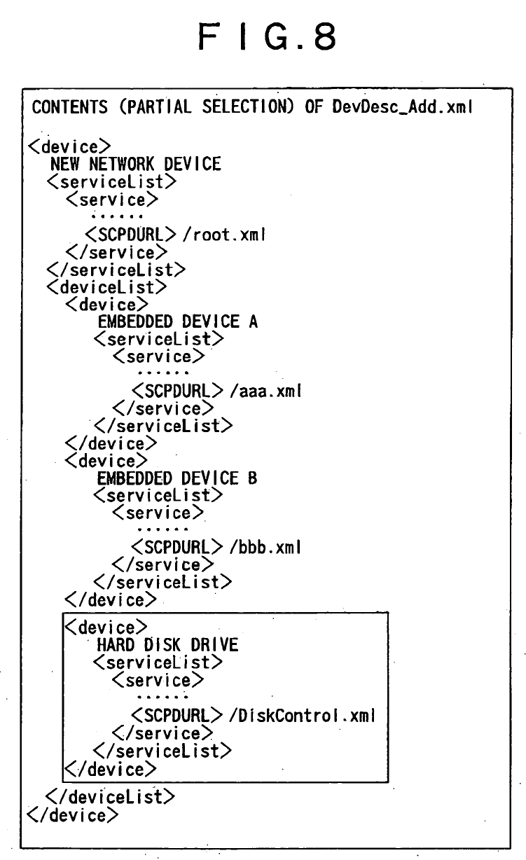

FIG. 7 is an example of the device description included in the network unit (device). FIG. 8 is an example of the device description restructured by the description restructuring and notification programs. The change of the device descriptions is explained with reference to FIGS. 7 and 8 when the procedure of the description restructuring and notification program is executed according to the flowchart of FIG. 6A if the extended peripheral device is connected to the network unit (device) 40 of FIG. 4.

The device description (DevDesc.xml) of FIG. 7 is partially selected, and indicates the same kind description as that in FIG. 2. If the hard disc drive is connected to the peripheral device connection I/F unit 50 of the network unit (device) 40 as indicated in FIG. 5 and the description restructuring and notification program is executed according to FIG. 6A, the description of FIG. 7 is restructured as indicated in FIG. 8. The partial selection of this restructured device description (DevDesc_Add.xml) of FIG. 8 indicates that the connected extended peripheral device (hard disc drive) is connected to the <device>tag as indicated by an enclosing thin line.

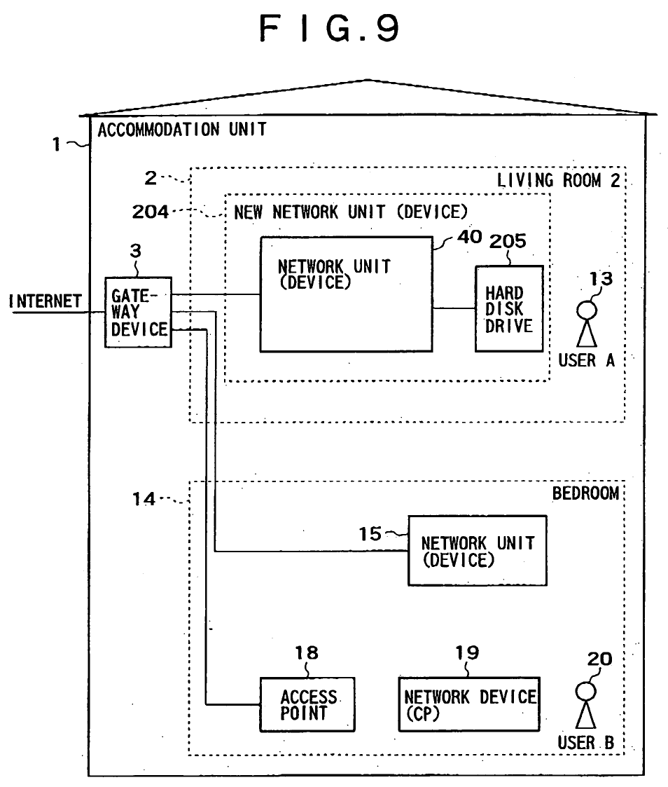

FIG. 9 is a block diagram of the customer station network structure for explaining the customer station network location of the network device of the first embodiment of the present invention. In FIG. 9, a numeric reference 204 is a new network device, a numeric reference 205 is a hard disc drive, and other numeric references are the same as the cases of FIGS. 1 and 4. The internal structure of the network unit (device) 40 of FIG. 9 is the same as FIG. 4, and the internal structure is not indicated. Further, the customer station network is the same as the case of FIG. 1.

As shown in FIG. 9, the customer station network of the residence 1 is connected to the public switched network including Internet via the gateway device 3. The customer station network includes the network unit (device) 40 of the first embodiment of the present invention, which is set in the living room 2, the network unit (device) 15 set in the bedroom 14, the wire cable network unit that is directly connected to the gateway device 3 as the access point 18, and the wireless network unit that is indirectly connected using radio transmission via the access point 18 in the same way as the network device (CP) 19 of the bedroom 14.

Then, the hard disc drive 205 as the embedded peripheral device is connected to the foregoing network unit (device) 40 and the device description that is indicated and explained in FIG. 8 is provided for the network device (CP) 19. That is to say, the foregoing network unit (device) 40 can be regarded as the new network device 204 including the hard disc drive 205 and the network unit (device) 40, which is indicated in FIG. 4, indicated by circumscribing using a dotted line in FIG. 9, from the point of view of the network device (CP) 19, thus the hard disc drive 205 can be utilized even from the remote user B 20 of the bedroom 14. As the actual example of the foregoing network unit (device) 40, there are the remote control device, the television set, the video camera, the DVD player, the hard disc recorder for storing the image and music contents, etc.

According to the first embodiment of the present invention, the embedded peripheral device connected to the network device can be utilized even from the remote user via the network. If the foregoing embedded peripheral device is removed, its state can be recognized correctly even from the foregoing user, and further it can be made to decide whether or not the remote user can use the embedded peripheral device freely.

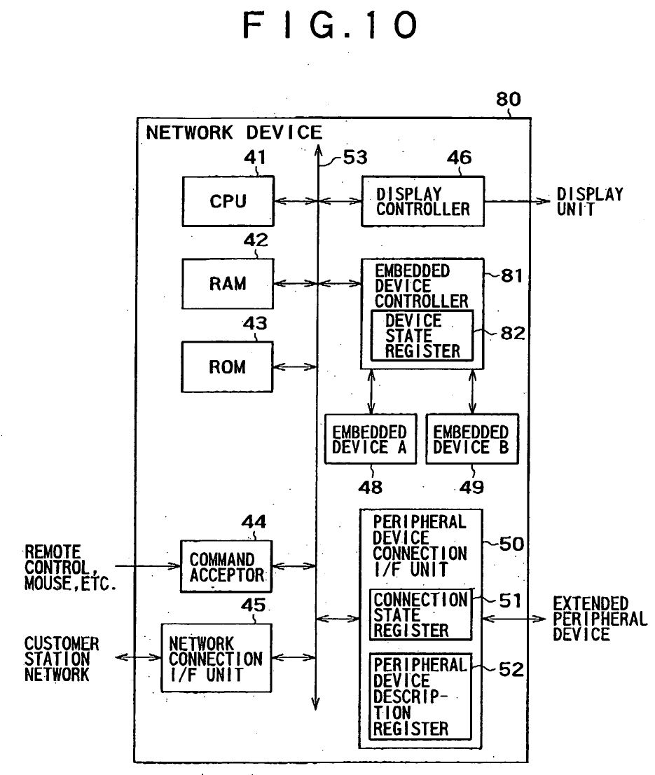

FIG. 10 is a block diagram of the network devices according to the second embodiment of the present invention. Here, the network devices of the second embodiment of the present invention are explained. In FIG. 10, a numeric reference 80 is a network device, a numeric reference 81 is an embedded device controller, a numeric reference 82 is a device state register, and other numeric references are the same as the case of FIG. 4.

The network device 80 of the second embodiment of the present invention is different from the first embodiment in that the embedded device controller 47 of the network unit (device) 40 of the first embodiment is modified to the embedded device controller 81 by setting the device state register 82 in the inside thereof Thus, explanation except the embedded device controller 81 of the network device 80 of the second embodiment of the present invention is omitted hereinafter.

The device state register 82 provided in the embedded device controller 81 of the network device 80 monitors an operating state of each embedded device. More particularly, if operating temperature and/or current consumption of each embedded device become abnormal, the device state register 82 stores their states by one-to-one correspondence with each embedded device and can issue a notification warning to the CPU 41.

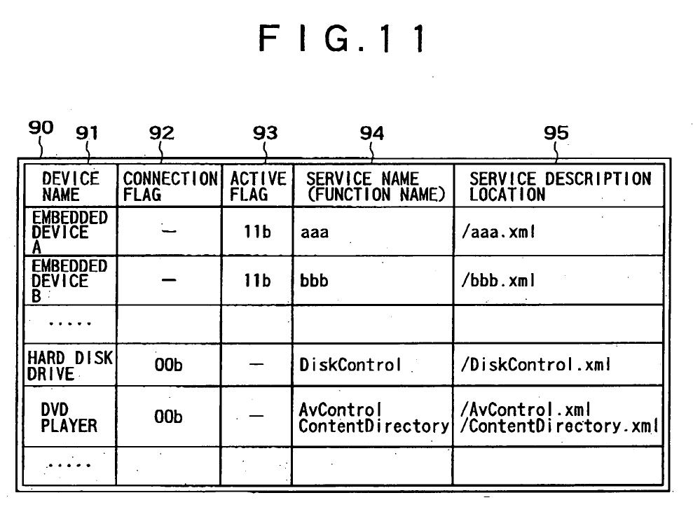

FIG. 11 is an example of a device information table 90 included in the network device of FIG. 10. The device information table 90 is hereinafter explained.

As indicated in FIG. 11, the device information table 90 is a table describing a device name 91 indicating the embedded peripheral device which can be provided for each embedded device included in the network device 80 of FIG. 10 and other network devices, a connection flag 92 which is the same as the connection flag 62 of FIG. 5 which can be edited by the user and indicates the state of reflecting in the device description, an active flag 93 which indicates an active state of the embedded device and the state of reflecting In the device description and is capable of editing by the user, a service name (function name) 94 provided by the embedded peripheral device and the embedded device described in the foregoing device name 91, and a service description location 95 corresponding to the foregoing service name (function name) 94 and indicating the service description and its location owned by the network device 80 in advance.

In the foregoing, the flag “11b” (“b” stands for binary) indicating the state of running and the state of being reflected in the device description is described in the active flag 93 if the embedded device in conformity with the device name 91 is running correctly. Further, the flag “00b” indicating a non-operational state that the embedded device does not run and the state of being reflected in the description is described. Further, the flag “01b” is described if the embedded device is the state of running and the state of not being reflected is the device description. The flag “10b” is described if the embedded device has the non-operational state and the state of being reflected in the device description. Further, the network device 80 of FIG. 10 can include the foregoing device information table 90 separately as a table of describing only the extended peripheral device portion such as the device information table 60 of FIG. 5 and as a table of describing only the embedded device portion.

The user can edit only a bit portion indicating the state of reflecting the foregoing active flag 93 in the description. The user can change the flags from “11b” to “01b” and from “01b” to “11b” Here, the initial value of the connection flag is “11b” in the state of turning on the power supply of the network device 80. Otherwise, the embedded device is in the non-operational state and the flag becomes “10b” indicating the state of being reflected in the description.

Then, the operation of the network device 80 is explained with reference to FIG. 10 If the embedded device fails to function.

If malfunction of the embedded device B 49 and embedded device A 48 managed by the embedded device controller 81 is detected, this embedded device controller 81 issues embedded device malfunction detection notification indicating that the embedded device fails to function for the CPU 41. Although an actual method for transmitting this embedded device malfunction detection notification is not indicated in FIG. 10, an interrupting signal can be used for wiring connection between the CPU 41 and the peripheral device connection I/F unit 50.

The CPU 41 accesses the device state register 82 included in the embedded device controller 81 so as to identify the embedded device that has detected malfunction. Then, the CPU 41 describes the flag “10b” in the active flag 93 of the device information table 90 of FIG. 11.

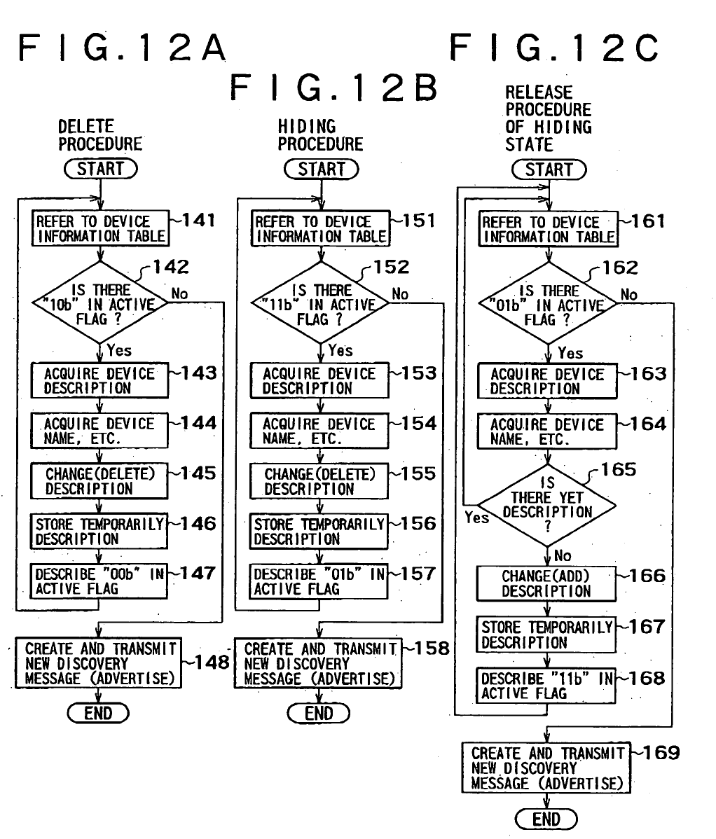

Here, the description restructuring and notification programs are activated as well when the user has changed the active flag 93 of the device information table 90 of FIG. 11. Such a change of the active flag 93 is made by the user in the case of deleting the foregoing embedded device from the device description so as to hide the internal embedded device in order not to provide for other network devices. In this case, to put it concretely, the user updates the operation flag 93 of respective embedded devices from “11b” to “01b.” In such a case, the description restructuring and notification program indicated in the flowchart of the hide procedure of FIG. 12B to be hereinafter described is activated. Further, in the case of releasing the hidden embedded device, the user updates the active flag 93 corresponding to the embedded device from “01b” to “11b.” In this case, the description restructuring and notification program indicated in the flowchart of the procedure of releasing the hiding state of FIG. 12C to be hereinafter described is activated.

FIGS. 12A, 12B, and 12C are flowcharts of executing the procedures of the description restructuring and notification programs of the network device of the second embodiment of the present invention. Then, these procedures are explained herein. The description restructuring and notification programs described herein are executed if the embedded device described in the device information table malfunctions or the bits for reflecting the active flag in the description are changed explicitly by the user.

First, the procedure of deleting information of the fault embedded device from the device description with reference to FIG. 12A is explained.

(1) If the fault of the embedded device is notified, the active flag of the device Information table is referred to, the line of describing “10b” in the active flag, namely, the line of indicating that the embedded device cannot be provided to the outside, is searched, and it is determined as a result of searching whether or not the corresponding line exists (steps 141 and 142).

(2) If it is determined that there is the line of describing “10b” in the active flag according to the determination of the step 142, the current device description is obtained from the memory, and further the device name and so forth are obtained from the device information table 90 (steps 143 and 144).

(3) The tag portion up to the </device>tag from the <device>tag describing the embedded device obtained at the step 144. Is deleted from the <deviceList>tag portion of the device description obtained at the step 143, and thus restructured device description is stored temporarily in the memory (steps 145 and 146).

(4) Then, the flag “00b” indicating that the fault embedded device is deleted from the device description is described in the active flag of the device information table. Then, returning to the procedures from the step 141, the procedure of a line for searching moves on and is executed (step 147).

(5) Then, according to the determination at the step 142, if the line of describing “10b” in the active flag does not exist in the device information table any more, multicasting transmission is made by creating a new advertise message describing URL for storing the latest device description (step 148).

Then, with reference to the flowchart of FIG. 12B, the procedure for deleting information of the extended peripheral device from the device description, in order to hide the internal embedded device, is explained.

(1) If the procedure for hiding the embedded device is executed, the active flag 93 of the device information table 90 is referred to, the line of describing “11b” in the active flag, namely, the line of indicating that the embedded device can be provided to the outside, is searched, and it is determined a result of searching whether or not the corresponding line exists as (steps 151 and 152).

(2) If it is determined that there is the line of describing “11b” in the active flag according to the determination of the step 152, the current device description is obtained from the. memory, and further the device name is obtained from the device information table 90 (steps 153 and 154).

(3) The tag portion up to the </device>tag from the <device>tag describing the embedded device obtained at the step 154 is deleted from the <deviceList.>tag portion of the device description obtained at the step 153, and thus the restructured device description is stored temporarily in the memory (steps 155 and 156).

(4) Then, the flag “01b” indicating that the hiding extended peripheral device is deleted from the device description is described in the active flag of the device information table. Then, returning to the procedures from the step 151, the procedure of a line for searching moves on and is executed (step 157).

(5) Then, according to the determination at the step 152, if the line of describing “11b” in the active flag does not exist in the device information table any more, multicasting transmission is made by creating a new advertise message describing URL for storing the latest device description (step 158).

Then, with reference to the flowchart of FIG. 12C, the procedure for adding information of the extended peripheral device to the device description, in order to release the hiding state of the embedded device, is explained.

(1) If the procedure for releasing the hiding state of the embedded device is executed, the active flag 93 of the device information table 90 is referred to, the line of describing “01b” in the active flag, namely, the line of indicating that the embedded device cannot be provided to the outside, is searched, and it is determined as a result of searching whether or not the corresponding line exists (steps 161 and 162).

(2) If it is determined that there is the line of describing “01b” in the active flag according to the determination of the step 162, the current device description is obtained from the memory, and further the device name, the service name, and the service description location are obtained from the device information table 90 (steps 163 and 164).

(3) It is determined whether or not the device name obtained at the step 164 has already been described in the device description obtained at the step 163, and if the device name has already been described, the procedure of a line for searching is executed by moving on to the step 161 (step 165).

(4) If the device name obtained at the step 164 is not described in the device description by determining at the step 165, the <device>tag is added to the <deviceList>tag portion of the device description obtained at the step 163, information obtained at the step 164 is added, and thus the restructured device description is temporarily stored in the memory (steps 166 and 167).

Then, the flag “11b” indicating that the embedded device for releasing the hiding state is added to the device description is described in the active flag of the device information table, returning to the procedures from the step 161, and the procedure of a line for searching moves on and is executed (step 168).

(6) Then, according to the determination at the step 162, if the line describing “01b” in the connection flag and indicating the release of the hiding state does not exist in the device information table any more, multicasting transmission is made by creating a new advertise message describing URL for storing the latest device description (step 169).

In the foregoing, the execution of the procedures of the description restructuring and notification programs are explained, and then the network device (CP) can obtain the restructured device description by receiving the foregoing new advertise message and accessing the destination URL.

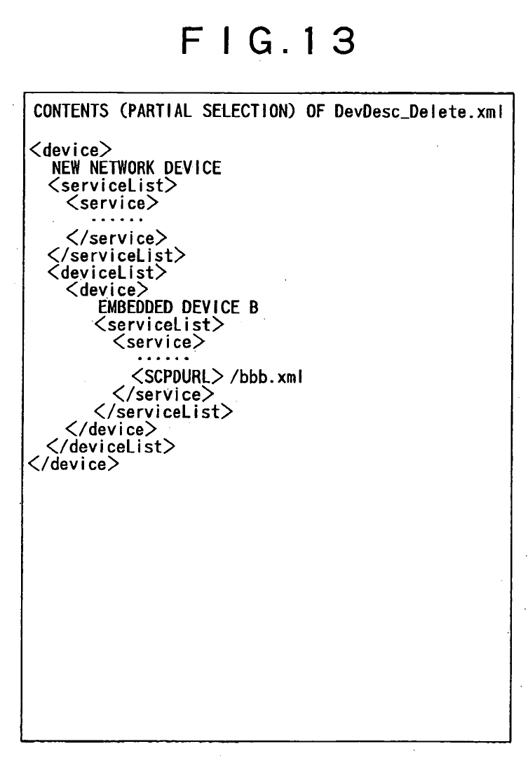

FIG. 13 is an example of the restructured device description by the procedure of FIG. 12. Then, the change of the device description, which is caused by the description restructuring and notification program of FIG. 12A in the case where the embedded device A 48 of the network device 80 falls to function, is explained with reference to FIG. 13.

An example of a partial selection of the restructured device description (DevDesc_Delete.xml) of FIG. 13 indicates the change from the device description of FIG. 7, and the <device>tag portion describing the embedded A of FIG. 7 is deleted by the procedure of FIG. 12A.

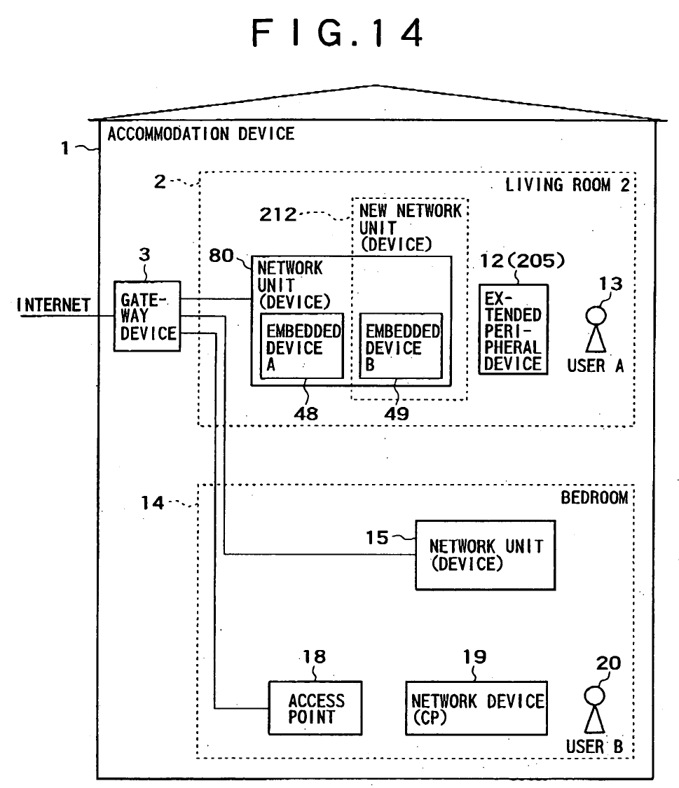

FIG. 14 is a block diagram of the customer station network for explaining the location of the network device of the customer station network of the second embodiment. In FIG. 14, a numeric reference 212 is a new network device, and other numeric references are the same as that of FIGS. 1 and 10. Here, the internal structure of the network unit (device.) 40 of FIG. 14 is the same as that of FIG. 10, and units other than the embedded device A 48 and the embedded device B 49 are not mentioned in the internal structure. Further, the customer station network is the same as FIG. 1.

As indicated in FIG. 14, the customer station network of the residence 1 includes the network unit (device) 80 of the second embodiment of the present invention, which is connected to a public switched network including Internet via the gateway device 3 and provided in the living room 2, the network unit (device) 15 provided in the bedroom 14, a wire cable network unit that is directly connected by the gateway device 3 in the same way as the access point 18, and a wireless network unit that is indirectly connected via the access point 18 in the same way as the network device (CP) 19 of the bedroom 14.

Then, an example explained herein indicates that the device description as shown in FIG. 13 is provided for the network device (CP) 19 since the embedded device A of the network device 80 is malfunctioning at the present time. That is to say, the foregoing network unit (device) 80 is regarded as a new network unit (device) 212 from the point of view of network device (CP) 19, as indicated in FIG. 14 by circumscribing using a dotted line, to be the network unit (device) 80 excluding the embedded device A 48 of FIG. 10. Thus, the user can exclude a risk of operating mistakenly, since the improperly working embedded device A 48 cannot be seen by the user B 20 of the remote bedroom 14.

According to the foregoing second embodiment of the present invention, if the embedded device fails to function, the user can acknowledge its state correctly.

Each of the abovementioned procedures of each embodiment of the present invention can be structured as the processing program, and this processing program can be stored in a memory device such as HD (Hard Disc), DAT (Digital Audio Tape), FD (Floppy Disc), MO (Magneto-optical Disc), DVD-ROM (Digital Versatile Disc-Read Only Memory), CD-ROM (Compact Disc Read Only Memory), etc., or provided via the network.

According to each of the abovementioned embodiments of the present invention, the device description can be restructured by identifying the device element arrangement automatically by recognizing the connection state of the extended peripheral device and the active state of the internal embedded devices by the network device as the devices in compliance with the UPnP standard or by triggering by the instruction from the user. Further, the device description restructured completely can be given to the network device as the control point.

In the foregoing, according to the embodiment of the present invention, the latest device element arrangement can be provided to the network device as the control point and its function can be shared securely via the network.

Further, according to the present invention, the user can select the function of providing to the foregoing network device, thus its functionality can be shared with a high degree of freedom. Further, since information for the same device element arrangement can be shared without having any time difference among the foregoing network devices, its functionality can be shared securely with a high degree of freedom from any network device.

Although the invention has been shown and described with respect to best mode embodiments thereof, it should be understood by those skilled in the art that the foregoing and various other changes, omissions, and additions in the form and detail thereof may be made therein without departing from the spirit and scope of the invention.

1. A digital device connected to a network, comprising:
a device description for describing a digital device arrangement as predetermined information in order to utilize a function provided by the digital device from another digital device, corresponding to Plug and Play (PnP) capable of providing the function to the other digital device by communicating the predetermined information via the network by the digital device, and
description restructuring means for updating the device description by detecting a change of an own device arrangement.

2. The network device according to claim 1, further comprising:
description notification means for notifying the device description updated by the description restructuring means to another network device.

3. The network device according to claim 2, comprising:
a device information table for storing a device name indicating an extended peripheral device capable of providing to at least another network device, a connection flag indicating a state of connecting the extended peripheral device and a state of being reflected in the device description, a service name included in the extended peripheral device described in the device name, and a service description location indicating a location for describing a service description corresponding to the service name in advance,
wherein the description restructuring means determine, by referring to the device information table when connecting the peripheral device, whether or not the peripheral device being connected can be informed publicly to the other network device and whether or not the extended peripheral device capable of being provided to the other network device is connected.

4. The network device according to claim 3, wherein the connection flag can be edited by a user.

5. The network device according to claim 2, comprising:
a device information table for storing a device name indicating an extended peripheral device capable of providing to a network device and an internal embedded device, a connection flag indicating at least a state of connecting the extended peripheral device and a state of being reflected in a device description, an active flag indicating an active state of the embedded device and the state of being reflected in a device description, a service name included in the extended peripheral device and the embedded device described in the device name, and a service description location indicating a location for describing the service description corresponding to the service name in advance,
wherein the description restructuring means determine, by referring to the table when connecting the extended peripheral device, whether or not the extended peripheral device can be informed publicly and provided for another network device, whether or not the extended peripheral device capable of being provided to the other network device is connected, and whether or not an internal embedded device is active.

6. The network device according to claim 5, wherein at least one of the connection flag and the active flag can be edited by the user.

7. The network device according to claim 3, further comprising:
a network connection I/F unit for connecting to a network;
a peripheral device connection I/F unit for connecting the extended peripheral device to be an extended function by the user;
a command receiver for receiving indication from the user;
a display controller for displaying a state of the network device;
two or more embedded devices; and
an embedded device controller for controlling the embedded device,
wherein the peripheral device connection I/P unit includes a register for storing a connection state and inherent information of the extended peripheral device.

8. The network device according to claim 3, further comprising:
a network connection I/F unit for connecting to a network;
a peripheral device connection I/F unit for connecting the extended peripheral device to be an extended function by the user;
a command receiver for receiving indication from the user;
a display controller for displaying a state of the network device;
two or more embedded devices; and
an embedded device controller for controlling the embedded device,
wherein the embedded device controller includes a register for storing an active state of each embedded device.

9. The network device according to claim 2, wherein a hard disc drive as the extended peripheral device is connected and the hard disc drive is accessed by the other network device that received the device description.

10. A method for processing information between a first device and a second device, wherein a device description for describing information for a structure of the peripheral device of the first device capable of connecting a peripheral device is transmitted to the second device via a network, and further a function of the peripheral device included in the first device can be utilized from the second device, comprising the steps of:
keeping information for the peripheral device included in the first device in a memory as a device information table;
referring to the device information table and determining whether or not a change is associated with the peripheral device of the first device;
if there is a change for the peripheral device as a result of determination, obtaining the device description and further obtaining a device name of the peripheral device for the change from the device information table;
updating the device description by processing information for the device description based on the obtained device name; and
transmitting information for indicating a location for storing the updated device description from the first device to the network.

11. The method for processing information according to claim 10, wherein the device information table stores the device name indicating the peripheral device capable of providing a function, a connection flag indicating a state of connecting the peripheral device and a state of being reflected in a device description, a service name included in the peripheral device described in the device name, and a service description location for indicating a location describing a service description in advance corresponding to the service name, further comprising the step of:
if the peripheral device is newly connected to the first device determining whether or not usage of the peripheral device being connected can be provided to the second device and whether or not the peripheral device capable of being provided to the second device is connected, by referring to the device information table.

12. The method for processing information according to claim 10, wherein the obtained information is added to a predetermined position of the device description and information for indicating that the device description is added is registered in the connection flag, after a restructured device description is stored in a memory.

13. The method for processing information according to claim 10, wherein a new advertise message describing URL for storing an updated device description is created and transmitted.

14. The method for processing information according to claim 10, wherein a peripheral device which has not yet been reflected in the device description is searched by referring to a device information table for determining whether or not a new peripheral device can be provided to the second device, it the peripheral device is newly added to the first device, information to be reflected in the device description is obtained from the device information table, the obtained information is added to the device description, information for adding new information to the device description is registered, the device description is updated, and multicasting transmission is made by creating the new advertise message describing URL for storing the updated device description.

15. The method for processing information according to claim 10, wherein a determining procedure is executed to determine whether or not the extended peripheral device is in a state of disconnecting the peripheral device by referring to the device information table, if it is found that the peripheral device is disconnected as a result of determination, the device description is obtained from the memory and a device name of a device which is removed from the device information table is obtained, the device description is updated by deleting associated information from the device description based on the obtained device name, information for indicating that a disconnected extended peripheral device is deleted from the device description is registered in the connection flag of the device information table, and multicasting transmission is made by creating a new advertise message describing URL for storing the updated device description.

16. The method for processing information according to claim 10, wherein a determining procedure is executed to determine whether or not the extended periphery device is in a hiding state of the extended peripheral device by referring to the device information table for executing a procedure of hiding the extended peripheral device, if it is found that the extended peripheral device is hidden as a result of determination, the device description is obtained from the memory and a device name associated with hiding is obtained from the device information table, the device description is updated by deleting an index associated with the extended peripheral device for hiding from the obtained device description, information for indicating that the extended peripheral device for hiding is deleted from the device description is registered in the device information table, and multicasting transmission is made by creating the new advertise message describing URL for storing the updated device description.

17. The method for processing information according to claim 10, wherein the first and second devices are devices in compliance with a UPnP standard, and the second device has a function as a control point for the first device.

18. The method for processing information according to claim 13, wherein the second device obtains the device description stored in the memory according to the URL.

19. The method for processing information according to claim 16, wherein the device description is updated for releasing by releasing a hiding state of the peripheral device being temporarily hidden by referring to the device information table.

20. A computer processable program for executing a method of reflecting a change for a peripheral device of a first device in a second device by transmitting a device description describing information associated with a peripheral device arrangement of the first device for allowing peripheral device connection to the second device via a network, comprising the steps of:
referring to device arrangement information stored in a memory for recording information associated with the peripheral device of the first device and determining whether or not the information indicates a change for the peripheral device of the first device;
if there is a change for the peripheral device as a result of determination, obtaining the device description and a device name of the peripheral device for the change from a device information table;
updating the device description by processing associated information for the device description based on the obtained device name; and
transmitting information for indicating a location for storing the updated device description from the first device to the network.
